(19) United States
(12) Patent Application Publication
(10) Pub. No.: US 2016/0099075 A1
(43) Pub. Date: Apr. 7, 2016

(54) FUSE ARRAY CIRCUIT AND SEMICONDUCTOR SYSTEM INCLUDING THE SAME

(71) Applicant: SK hynix Inc., Gyeonggi-do (KR)

(72) Inventor: Hyun-Su YOON, Gyeonggi-do (KR)

(21) Appl. No.: 14/663,192

(22) Filed: Mar. 19, 2015

(30) Foreign Application Priority Data
Oct. 1, 2014 (KR) 10-2014-0132567

(51) Int. Cl. G11C 17/18; G11C 17/16

(52) U.S. Cl. CPC G11C 17/18; G11C 17/16

(57) ABSTRACT

A fuse array circuit includes a power generation block suitable for generating a driving power to be level-shifted at least once in a read operation period, a word line driving block suitable for driving a word line by using the driving power, and a fuse array suitable for outputting information programmed in a fuse that is activated by the driven word line through a bit line.

### CROSS-REFERENCE TO RELATED APPLICATIONS

The present application claims priority of Korean Patent Application No. 10-2014-0132567, filed on Oct. 1, 2014, which is incorporated herein by reference in its entirety.

### BACKGROUND

1. Field

Exemplary embodiments of the present invention relate to a semiconductor design technology and, more particularly, to a fuse array circuit.

2. Description of the Related Art

In general, a semiconductor device such as double data rate synchronous DRAM (DDR SDRAM) includes a fuse circuit. The fuse circuit may store various pieces of information to be used for the operation of the semiconductor device. For example, the fuse circuit stores various result values that are obtained through a test operation for the semiconductor device, and the semiconductor device uses the result values stored in the fuse circuit when performing the operation. Accordingly, even though the characteristics of brand new semiconductor memory devices are slightly different from each other, all the semiconductor memory devices may perform substantially the same operations based on information stored in the fuse circuit. As a result, the fuse circuit serves as the basis for providing an environment in which a plurality of semiconductor devices may perform substantially the same operation.

The fuse circuit includes a plurality of fuses in which various pieces of information are stored. For convenience, a series of operations for storing certain information in a fuse will be referred to as a “programming operation”. A method for programming certain information in a fuse may be classified into a physical scheme and an electrical scheme.

In the physical scheme, a fuse is cut by blowing the fuse using a laser beam, and the like, according to information to be programmed. The fuse used in the physical scheme is called a physical type fuse. Particularly, when cutting the fuse using a laser beam, it is also called a laser blowing type fuse. Physical type fuses may only be programmed in the wafer state, before the semiconductor device is packaged.

In the electrical scheme, the connection state of a fuse is changed by applying excessive current to the fuse, according to information to be programmed. The fuse used in the electrical scheme is called an electrical type fuse. Electrical type fuses may be classified into anti-type fuses and blowing type fuses. The anti-type fuses change from an initial open state to a shorted state by applying excessive current. The blowing type fuses change from an initial shorted state to an open state by applying excessive current. Such electrical type fuses are advantageous over physical type fuses in that the programming operations are possible after the wafer state, that is, even in a packaged state. Accordingly, recent trends have shown that the electrical scheme is preferred to the physical scheme in semiconductor device design.

Since semiconductor devices are required to perform various operations by consumers, they have been designed to try and satisfy that request. Performing various operations means an increase in the number of fuses corresponding to each operation. Recently, technologies for efficiently managing a larger number of fuses have been researched, resulting in the emergence of a fuse array circuit.

FIG. 1 is a diagram illustrating a conventional fuse array circuit.

Referring to FIG. 1, the fuse array circuit has a plurality of fuse cells disposed in an array form. Hereinafter, for the purpose of convenience, one fuse cell 110 of a plurality of fuse cells will be described.

The fuse cell 110 includes a fuse F and a selection transistor TR. The fuse F is coupled to a program word line WLP1 and the selection transistor TR is coupled to a read word line WLR1. The fuse F stores information and may be designed using various types of fuses, as described above.

Hereinafter, a simple read operation of the fuse array circuit will be described. For convenience, it is assumed that the fuse array circuit stores predetermined information through a programming operation.

In a read operation for outputting information programmed in the fuse F, a predetermined voltage is applied to the program word line WLP1 and the read word line WLR1. Then, a bit line BL1 may have a voltage level corresponding to the information programmed in the fuse F. That is, when the fuse F is in an open state, the bit line BL1 substantially maintains a precharged voltage, and when the fuse F is in a short state, since the predetermined voltage is transferred to the bit line BL1 via the fuse F and the selection transistor TR, the bit line BL1 is driven to a voltage level corresponding to the predetermined voltage. Although not illustrated in the drawing, a circuit for detecting and outputting the voltage level of the bit line BL1 in the read operation is coupled to the bit line BL1. As a result, the information programmed in the fuse F is outputted through the bit line BL1 so that the semiconductor device performs a predetermined operation using the outputted information.

As described above, the fuse F may enter the open state or the short state through the programming operation. Ideally, a fuse F in the open state and a fuse F in the short state should have constant resistance values, respectively. However, actual resistance values of fuses F may be slightly different from each other. Accordingly, sensing (or detecting) operation timing may be set based on an assumption that the fuses F have the worst possible resistance value.

Furthermore, as described above, a predetermined voltage is applied to the read word line WLR1. When the voltage level of the read word line WLR1 is too low, the timing of the sensing operations may be delayed, and when the voltage level of the read word line WLR1 is too high, excessive stress may be applied to a transistor coupled to the read word line WLR1. Accordingly, the voltage level of the read word line WLR1 may be regarded as one of the important factors to be selected.

### SUMMARY

Various embodiments are directed to a fuse array circuit capable of controlling a read operation of the fuse array circuit and stably outputting information programmed in a fuse.

In an embodiment, a fuse array circuit may include: a power generation block suitable for generating a driving power that is level-shifted at least once in a read operation period; a word line driving block suitable for driving a word line by using the driving power; and a fuse array suitable for outputting information programmed in a fuse that is activated by the driven word line through a bit line.

The read operation period may include first and second read periods, and the driving power may have a first voltage level in the first read period and have a second voltage level in the second read period.

The power generation block may include: a first supply section suitable for supplying a power having the first voltage level to the driving power; and a second supply section suitable for supplying a power having the second voltage level to the driving power.

The fuse array circuit may further include: a selection transistor coupled between the fuse and the bit line.

The word line may include: a program word line coupled to the fuse; and a read word line coupled to the selection transistor.

The driving power may be applied to the read word line.

The first voltage level may be higher than the second voltage level.

In an embodiment, a fuse array circuit may include: a power generation block suitable for generating a driving power that is level-shifted at least once in a read operation period; a level control block suitable for controlling a voltage level of the driving power based on state information of each of a plurality of fuses; a word line driving block suitable for driving a word line corresponding to each of the fuses by using the driving power; and a fuse array suitable for outputting information programmed in a fuse that is activated by the corresponding word line of the fuses through a bit line.

The state information of each of the fuses may correspond to a resistance value of each of the fuses after a programming operation.

The voltage levels of the driving power may be different from one another according to resistance values of the fuses.

A slope of a voltage level of the bit line may be proportional to a voltage level of the driving power.

In an embodiment, a semiconductor system may include: a semiconductor device with a fuse array circuit suitable for controlling a read operation period of the fuse array circuit based on initialization time information; and a controller suitable for providing the initialization time information and controlling the semiconductor device after the read operation period.

The fuse array circuit may include: a power generation block suitable for generating a driving power to be level-shifted at least once in the read operation period; a level control block suitable for controlling a voltage level of the driving power based on the initialization time information; a word line driving block suitable for driving a word line by using the driving power; and a fuse array suitable for outputting information programmed in a fuse that is activated by the driven word line through a bit line.

A plurality of fuses included in the fuse array may have sensing operation time points corresponding to the initialization time information.

The level control block may fix a level shifting point in time of the driving power to a predetermined point in time, and control the voltage level of the driving power based on the initialization time information.

The level control block may fixe the voltage level of the driving power to a predetermined level, and control a level shifting in time point in time of the driving power based on the initialization time information.

### BRIEF DESCRIPTION OF THE DRAWINGS

FIG. 1 is a diagram illustrating a conventional fuse array circuit.

FIG. 2 is a block diagram illustrating a fuse array circuit in accordance with an embodiment of the present invention.

FIG. 3 is a detailed diagram of a power generation block shown in FIG. 2.

FIG. 4 is a waveform diagram for explaining an operation of the power generation block shown in FIG. 3.

FIG. 5 is a block diagram illustrating a fuse array circuit in accordance with an embodiment of the present invention.

FIG. 6 is a waveform diagram for explaining an operation of a power generation block shown in FIG. 5.

FIG. 7 is a block diagram illustrating a semiconductor system in accordance with an embodiment of the present invention.

FIG. 8 is a detailed diagram of a fuse array circuit shown in FIG. 7.

FIGS. 9 and 10 are waveform diagrams for explaining an operation of a power generation block shown in FIG. 8.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

It is also noted that in this specification, “connected/coupled” refers to one component not only directly coupling another component but also indirectly coupling another component through an intermediate component. In addition, a singular form may include a plural form as long as it is not specifically mentioned. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween. When a first layer is referred to as being “on” a second layer or “on” a substrate, it not only refers to where the first layer is formed directly on the second layer or the substrate but also where a third layer exists between the first layer and the second layer or the substrate.

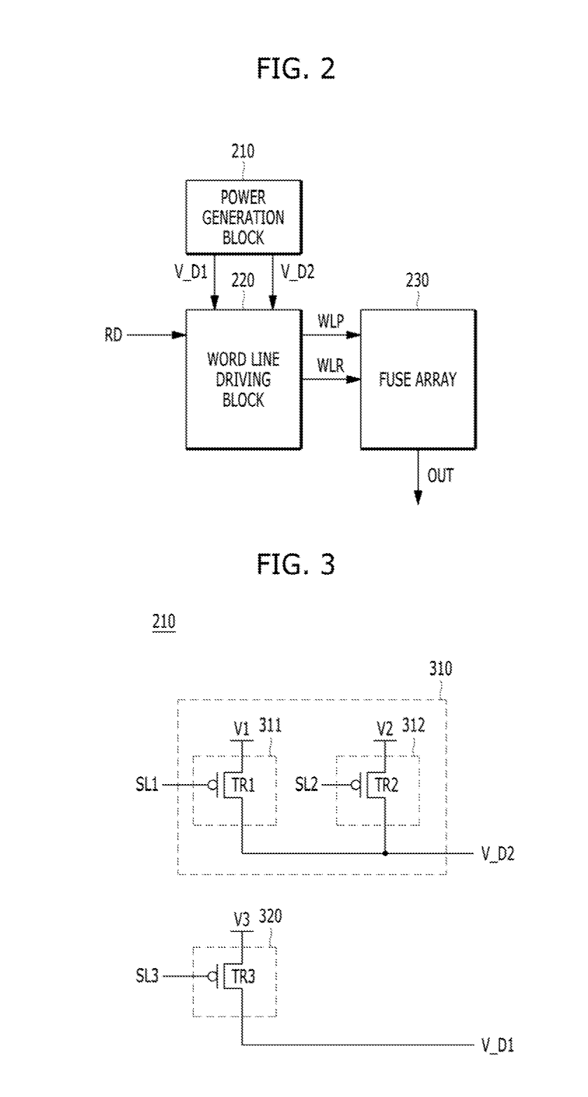

FIG. 2 is a block diagram illustrating a fuse array circuit in accordance with an embodiment of the present invention.

Referring to FIG. 2, the fuse array circuit may include a power generation block 210, a word line driving block 220, and a fuse array 230.

The power generation block 210 generates a first driving power V_D1 and a second driving power V_D2 for driving a program word line WLP and a read word line WLR, respectively. The first driving power V_D1 is a power for driving the program word line WLP and the second driving power V_D2 is a power for driving the read word line WLR. The second driving power V_D2 is level-shifted at least once in a read operation, which will be described later. The level shifting represents that a voltage level of the second driving power V_D2 is changed from a certain level to another level.

The word line driving block 220 receives the first driving power V_D1 and the second driving power V_D2 in response to a read command signal RD, and drives the program word line WLP and the read word line WLR. The read command signal RD is activated in the read operation of the fuse array circuit, where the read operation represents an operation for outputting information programmed in a fuse after a programming operation of the fuse array circuit.

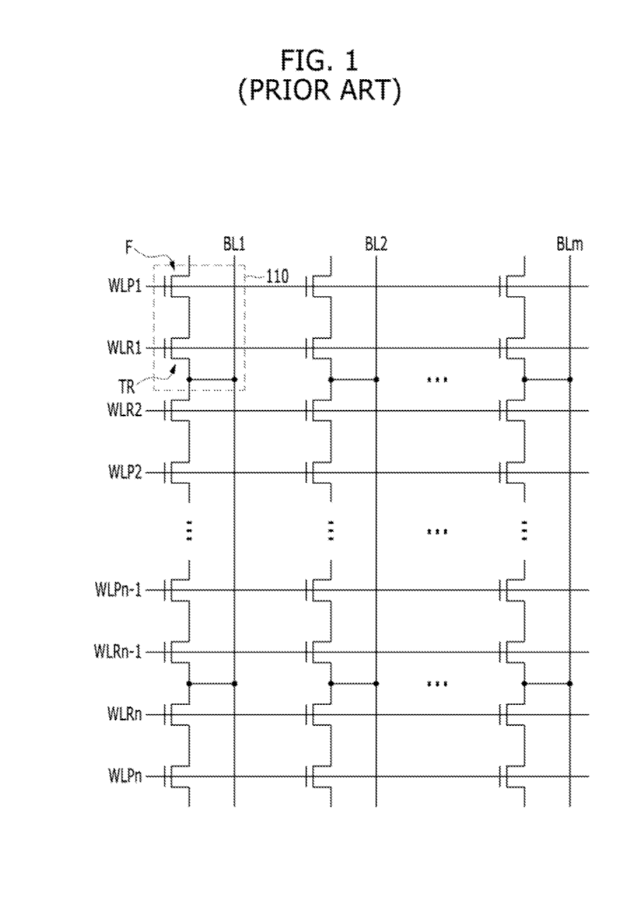

The fuse array 230 stores desired information through the programming operation, and includes a plurality of fuse cells. For convenience, the fuse array 230 is assumed to correspond to FIG. 1. That is, the fuse array 230 has a structure in which the fuse cells are coupled to one another in an array form, where each fuse cell may include the fuse F and the selection transistor TR, as illustrated in FIG. 1. In this case, the fuse F is coupled to the program word line WLP and the selection transistor TR is coupled to the read word line WLR. Accordingly, when the read word line WLR is activated, the fuse array 230 outputs information programmed in a corresponding fuse F through a corresponding bit line BL.

In the fuse array circuit in accordance with an embodiment of the present invention, in the read operation of the fuse array circuit, it may be possible to adjust the voltage level of the second driving power V_D2 for driving the read word line WLR, thereby more stably outputting information programmed in the corresponding fuse F.

FIG. 3 is a detailed diagram of the power generation block 210 shown in FIG. 2.

Referring to FIG. 3, the power generation block 210 may include a first power generation unit 310 and a second power generation unit 320.

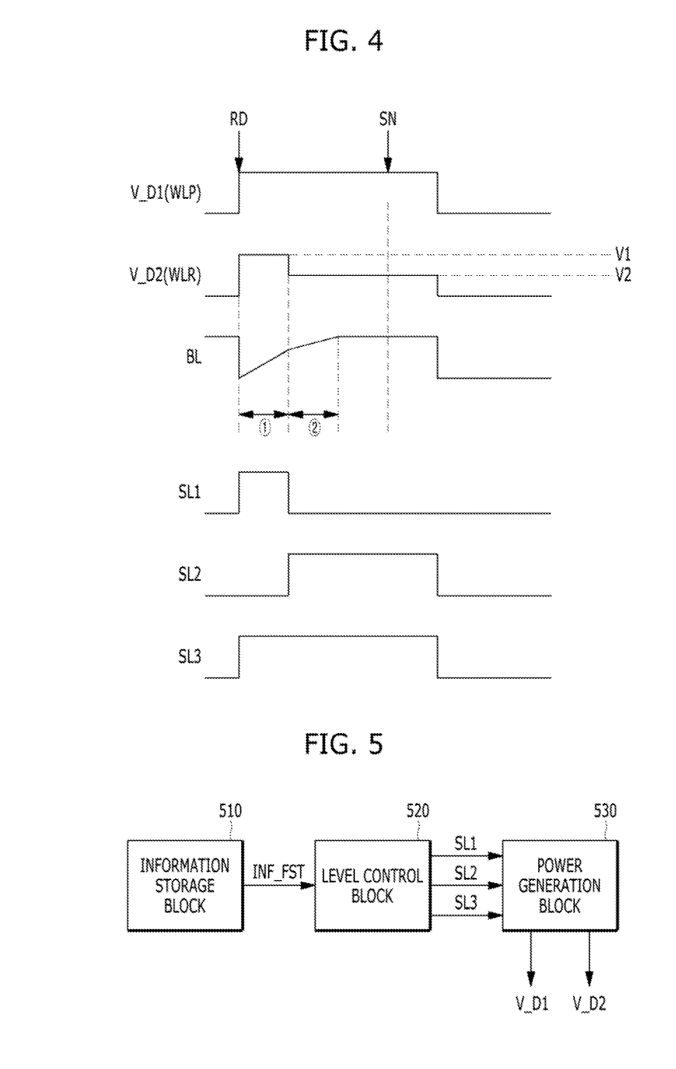

The first power generation unit 310 generates the second driving power V_D2, and includes a first supply section 311 and a second supply section 312. The first supply section 311 supplies power V1 having a first voltage level to the second driving power V_D2, and may include a first transistor TR1 for coupling a power V1 terminal having the first voltage level to the second driving power V_D2 terminal in response to a first selection signal SL1. The second supply section 312 supplies power V2 having a second voltage level to the second driving power V_D2, and includes a second transistor TR2 for coupling a power V2 terminal having the second voltage level to the second driving power V_D2 terminal in response to a second selection signal SL2. The first and second selection signals SL1 and SL2 will be described later with reference to FIG. 4.

The second power generation unit 320 generates the first driving power V_D1, and may include a third transistor TR3 for coupling a power V3 terminal of a third voltage level to the first driving power V_D1 terminal in response to a third selection signal SL3. The third selection signal SL3 will be described later with reference to FIG. 4. The power V3 having the third voltage level may be changed according to design, and has substantially the same voltage level as that of the power V1 having the first voltage level, for example.

FIG. 4 is a waveform diagram for explaining an operation of the power generation block 210 shown in FIG. 3, and illustrates the first driving power V_D1, the second driving power V_D2, the bit line BL, and the first to third selection signals SL1, SL2, and SL3.

Hereinafter, with reference to FIGS. 2 to 4, the read operation of the fuse array circuit will be described. For the purpose of convenience, a period until the read command signal RD is activated in the fuse array circuit and information programmed in the fuse F is outputted will be defined as a ‘read operation period’, and the read operation period is classified into an initial read period \textcircled{1} and a subsequent read period \textcircled{2}. The fuse F is assumed to be in a short state by the programming operation.

When the read command signal RD is activated, the first selection signal SL1 and the third selection signal SL3 are activated. Accordingly, the power V3 of the third voltage level is supplied to the first driving power V_D1 and the power V1 having the first voltage level is supplied to the second driving power V_D2. In this case, the first selection signal SL1 is activated for the initial read period \textcircled{1}. That is, the second driving power V_D2 is driven to the power V1 having the first voltage level in the initial read period \textcircled{1}, so that the voltage level of the bit line BL rises with a slope corresponding to the power V1 having the first voltage level. Then, the second selection signal SL2 is activated for the subsequent read period \textcircled{2}. Accordingly, the power V2 having the second voltage level is supplied to the second driving power V_D2. That is, the second driving power V_D2 is driven to the power V2 having the second voltage level in the subsequent read period \textcircled{2}, so that the voltage level of the bit line BL rises with a slope corresponding to the power V2 having the second voltage level. Then, the fuse array circuit has a sensing operation point in time SN after the voltage level of the bit line BL sufficiently rises. The sensing operation point in time SN represents a point in time at which information programmed in a fuse is outputted. In the fuse array circuit as described above, the information programmed in the fuse F may be outputted through a series of operations up to the sensing operation point in time SN after the read command signal RD is activated.

FIG. 4 illustrates an example in which a small margin is set between the end point in time of the subsequent read period \textcircled{2} and the sensing operation point in time SN for the purpose of a stable sensing operation, and the read operation of the fuse array circuit is performed. However, in an ideal operation in accordance with the embodiment of the present invention, the sensing operation point in time SN may also be set at the end point in time of the subsequent read period \textcircled{2}.

In the read operation of the fuse array circuit, the second driving power V_D2 for driving the read word line WLR may be changed from the power V1 having the first voltage level to the power V2 having the second voltage level. Through such an operation, it may be possible to stably output the information programmed in the fuse F.

In the read operation period of the fuse array circuit, when the initial read period \textcircled{1} is slightly increased, the voltage level of the bit line BL may rise more quickly, which represents that the sensing operation point in time SN may be set more quickly. Meanwhile, when the read word line WLR is continuously driven by the power V1 having the first voltage level, since undesired stress is accumulated in the transistor TR coupled to the read word line WLR, an abnormal operation may occur. However, in the fuse array circuit, the voltage level of the read word line WLR is changed in the read operation, so that it may be possible to minimize stress which may be accumulated in the transistor TR.

FIG. 5 is a block diagram illustrating a fuse array circuit in accordance with an embodiment of the present invention.

Referring to FIG. 5, the fuse array circuit may include an information storage block 510, a level control block 520, and a power generation block 530.

The information storage block 510 stores state information INF_FST of a fuse after a programming operation. Hereinafter, the state information INF_FST will be briefly described.

As described above, a fuse stores information through the programming operation, and the states of the fuse after the programming operation are formed differently for various reasons. In general, a fuse shorted through the programming operation has a resistance value lower than that of an opened fuse. However, all shorted fuses do not have substantially the same resistance value. That is, shorted fuses generally form a low resistance value and do not have substantially the same resistance value. This may be changed according to power applied in the programming operation or a process state of a fuse. As a result, even though fuses are shorted, all the fuses do not have substantially the same resistance value, and the state information INF_FST represents information corresponding to the resistance value.

The level control block 520 adjusts the voltage levels of the first driving power V_D1 and the second driving power V_D2 in response to the state information INF_FST, and generates the first to third selection signals SL1 to SL3 in response to the state information INF_FST. Although a detailed configuration of the level control block 520 is omitted, the level control block 520 may be designed such that the voltage levels of the first to third selection signals SL1 to SL3 are set according to the state information INF_FST in consideration of the configuration of the power generation block 530.

The power generation block 530 generates the first driving power V_D1 and the second driving power V_D2 in response to the first to third selection signals SL1 to SL3. Although not illustrated in FIG. 5, the first driving power V_D1 and the second driving power V_D2 generated in the power generation block 530 may be applied to the word line driving block 220 shown in FIG. 2. The power generation block 530 may have the same configuration as the power generation block 210 shown in FIG. 3, and the voltage levels of the first to third selection signals SL1 to SL3 may be adjusted, thereby adjusting a voltage level that is applied to the first driving power V_D1 and the second driving power V_D2.

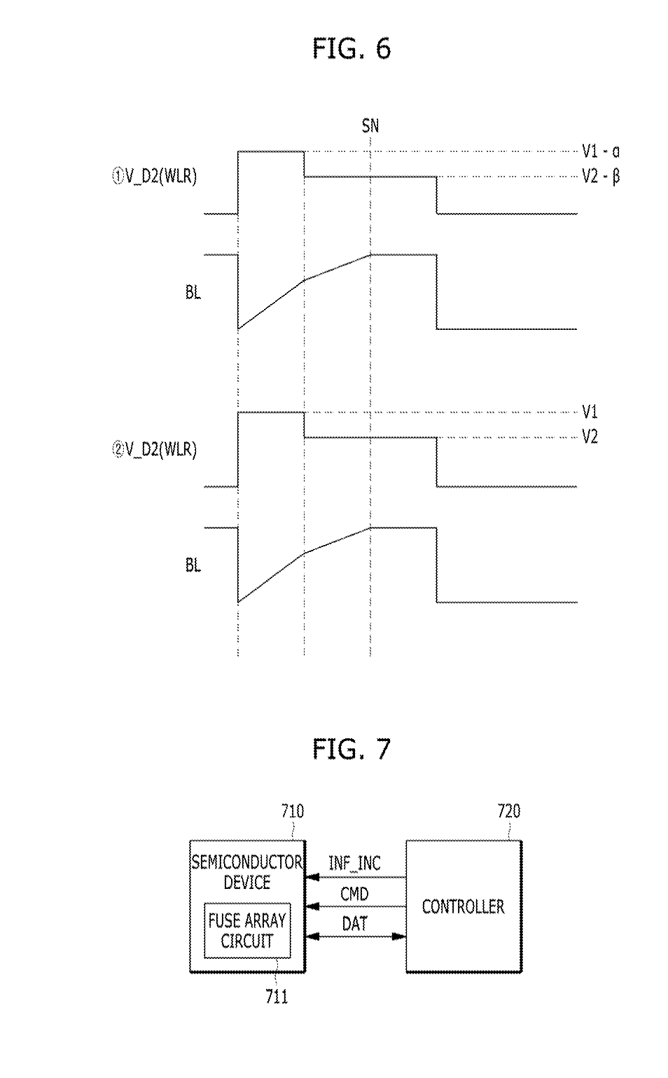

FIG. 6 is a waveform diagram for explaining an operation of the power generation block 530 shown in FIG. 5.

For convenience, two cases of a fuse shorted through the programming operation will be described as an example. In case \textcircled{1}, a resistance value of a fuse shorted through an ideal programming operation is very small, and in the case of \textcircled{2}, a resistance value of a shorted fuse is larger than that of the case of \textcircled{1}.

In case \textcircled{1}, in the read operation of the fuse array circuit, the second driving power V_D2 has a voltage level of V1-α and a voltage level of V2-β. The bit line BL has a voltage level of a slope corresponding to the second driving power V_D2. As described above, the voltage level of V1-α and the voltage level of V2-β of the second driving power V_D2 may be generated by adjusting the voltage levels of the first selection signal SL1 and the second selection signal SL2.

In case \textcircled{2}, in the read operation of the fuse array circuit, the second driving power V_D2 has a voltage level of V1 and a voltage level of V2. When comparing case \textcircled{2} with case \textcircled{1}, the voltage level of the second driving power V_D2 in case \textcircled{2} is higher than that of the second driving power V_D2 in case \textcircled{1} by α and β. However, since the resistance value of the fuse in case \textcircled{2} is higher than that of the fuse in case \textcircled{1}, the bit lines BL in case \textcircled{1} and case \textcircled{2} may have substantially the same voltage level.

As a result, as described above, even though the resistance values of shorted fuses are different from each other, as in cases \textcircled{1} and \textcircled{2}, results outputted through the bit lines BL may be controlled to be substantially equal to each other. This represents that time points at which a sensing operation is possible are substantially equal to each other in cases \textcircled{1} and \textcircled{2}.

In the fuse array circuit, even though respective resistance values of a plurality of fuses are different from one another as a result of the programming operation, it may be possible to set sensing operation time points SN for the fuses to be substantially equal to one another.

FIG. 7 is a block diagram illustrating a semiconductor system in accordance with an embodiment of the present invention.

Referring to FIG. 7, the semiconductor system may include a semiconductor device 710 and a controller 720.

The semiconductor device 710 performs various operations under the control of the controller 720, and may store data DAT or output the stored data DAT under the control of the controller 720. The semiconductor device 710 includes a fuse array circuit 711, where a read operation period of the fuse array circuit 711 is controlled in response to initialization time information INF_INC provided from the controller 720. The initialization time information INF_INC corresponds to an initialization completion time of the semiconductor device 710, where the controller 720 may control the initialization completion time of the semiconductor device 710.

The controller 720 controls the semiconductor device 710 after the read operation period of the fuse array circuit 711, and allows the semiconductor device 710 to store the data DAT or to output the stored data DAT according to a command signal CMD after the read operation period of the fuse array circuit 711.

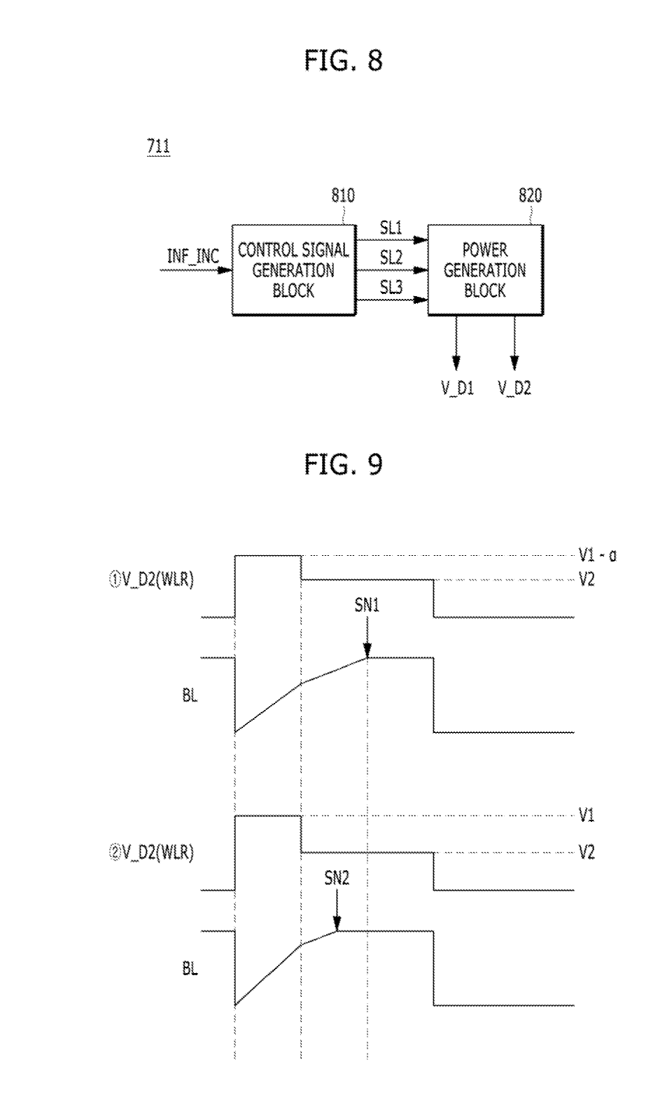

In the semiconductor system, the read operation period of the fuse array circuit 711 may be controlled according to the initialization time information INF_INC. This will be described in detail with reference to FIGS. 8 to 10.

The read operation period of the fuse array circuit 711 represents a period in which information programmed in the fuse array circuit 711 is loaded to the semiconductor device 710. Accordingly, the completion point in time of the read operation period corresponds to the point in time at which all the programmed information has been loaded, and represents that the initialization operation of the semiconductor device 710 has been completed and the controller 720 has controlled the semiconductor device 710 to be in a standby state.

FIG. 8 is a detailed diagram of the fuse array circuit 711 shown in FIG. 7.

Referring to FIG. 8, the fuse array circuit 711 may include a control signal generation block 810 and a power generation block 820.

The control signal generation block 810 generates the first to third selection signals SL1 to SL3 according to the initialization time information INF_INC, and the power generation block 820 generates the first driving power V_D1 and the second driving power V_D2 in response to the first to third selection signals SL1 to SL3. Although not illustrated in FIG. 8, the first driving power V_D1 and the second driving power V_D2 generated in the power generation block 820 may be applied to the word line driving block 220 of FIG. 2.

The power generation block 830 may have the same configuration as the power generation block 210 shown in FIG. 3, and it may be possible to adjust the voltage levels of the first to third selection signals SL1 to SL3, thereby adjusting a voltage level that is applied to the first driving power V_D1 and the second driving power V_D2.

In the semiconductor system, the voltage levels of the first driving power V_D1 and the second driving power V_D2 may be adjusted according to the initialization time information INF_INC, so that it may be possible to adjust the read operation completion point in time of the fuse array circuit 711, that is, the initialization operation completion point in time of the semiconductor device 710.

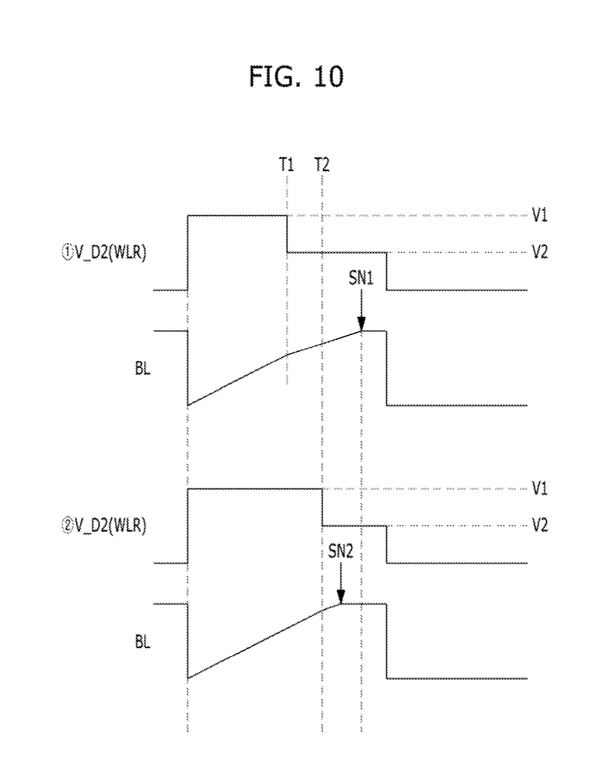

FIGS. 9 and 10 are waveform diagrams for explaining the operation of the power generation block 820 shown in FIG. 8. As described above, in the semiconductor system, the read operation period of the fuse array circuit 711 may be adjusted according to the initialization time information INF_INC. A circuit and a method for adjusting the initialization operation completion point in time may be designed in various ways, and the methods of FIGS. 9 and 10 will be described as an example in the present specification.

FIG. 9 illustrates an embodiment in which the voltage level of the second driving power V_D2 is adjusted to adjust the read operation period of the fuse array circuit 711. For convenience, it is assumed that fuses shorted through the programming operation have substantially the same resistance value.

In case \textcircled{1}, in the read operation period of the fuse array circuit, the second driving power V_D2 is level-shifted from a voltage level of V1-α to a voltage level of V2. Next, in case \textcircled{2}, in the read operation period of the fuse array circuit, the second driving power V_D2 is level-shifted from a voltage level of V1 to the voltage level of V2. In other words, the second driving power V_D2 has the voltage level of V1-α in an initial read period of case \textcircled{1} and has the voltage level of V1 in an initial read period of case \textcircled{2}. The second driving power V_D2 has substantially the same voltage level of V2 in read periods after cases \textcircled{1} and \textcircled{2}.

As in case \textcircled{2}, when the voltage level of the second driving power V_D2 is high in the initial read period, the voltage level of the bit line BL is driven to a large slope. This represents that the voltage level of the bit line BL rises more quickly. Meanwhile, the voltage level of the bit line BL in case \textcircled{1} rises more slowly. The difference in the slopes of the bit lines BL causes a difference in the time points at which the sensing operation is possible and, as seen from the drawing, the sensing operation point in time SN2 of case \textcircled{2} is faster than the sensing operation point in time SN1 of case \textcircled{1}.

As a result, the voltage level of the second driving power V_D2 may be adjusted according to the initialization time information INF_INC, which represents that it may be possible to adjust the read operation period of the fuse array circuit 711 according to the initialization time information INF_INC.

FIG. 10 illustrates an embodiment in which a driving time of the second driving power V_D2 is adjusted to adjust the read operation period of the fuse array circuit 711.

In case \textcircled{1}, in the read operation period of the fuse array circuit, the second driving power V_D2 is level-shifted from the voltage level of V1 to the voltage level of V2. Next, in case \textcircled{2}, similarly to case \textcircled{1}, the second driving power V_D2 is level-shifted from the voltage level of V1 to the voltage level of V2. However, in case \textcircled{1}, an initial read period and a subsequent read period are separated from each other on the basis of a point in time ‘T1’, and in case \textcircled{2}, the initial read period and the subsequent read period are separated from each other on the basis of a point in time ‘T2’. That is, the initial read period of case \textcircled{2} is longer than that of case \textcircled{1}. Accordingly, as seen from the drawing, the sensing operation point in time SN2 of case \textcircled{2} is faster than the sensing operation point in time SN1 of case \textcircled{1}.

As a result, the driving time of the second driving power V_D2 may be adjusted according to the initialization time information INF_INC, which represents that it may be possible to adjust the read operation period of the fuse array circuit 711 according to the initialization time information INF_INC.

As described in FIGS. 9 and 10, in the semiconductor system, the read operation period may be adjusted according to the initialization time information INF_INC, which represents that it may be possible to adjust the initialization operation completion point in time of the semiconductor device 710 according to the initialization time information INF_INC.

As a result, in the semiconductor system, the fuse array circuit 711 of the semiconductor device 710 may complete a read operation according to the initialization time information INF_INC provided by the controller 720, so that the semiconductor device 710 may complete an initialization operation. Furthermore, the controller 720 may stably perform an input/output operation of data DAT together with the semiconductor device 710 after the initialization operation of the semiconductor device 710.

The fuse array circuit in accordance with the embodiment of the present invention performs a read operation by using the second driving power V_D2 that is level-shifted at least once in a read operation period, thereby stably outputting information programmed in a fuse. Furthermore, the semiconductor system may control the semiconductor device 710 to complete an initialization operation according to an initialization completion point in time determined by the controller 720.

Although various embodiments have been described for illustrative purposes, it will be apparent to those skilled in the art that various changes and modifications may be made without departing from the spirit and scope of the invention as defined in the following claims.

In the aforementioned embodiments, an example has been used in which the voltage level of the second driving power V_D2 is adjusted in the read operations of the fuse array circuit. However, in the read operations, the second driving power V_D2 may also be adjusted similarly to the first driving power V_D1, and the first driving power V_D1 and the second driving power V_D2 may be simultaneously adjusted.

In addition, the positions and types of transistors in the aforementioned embodiments can be realized differently depending on the polarity of inputted signals as well as other design considerations.

What is claimed is:

1. A fuse array circuit comprising:
a power generation block suitable for generating a driving power that is level-shifted at least once in a read operation period;
a word line driving block suitable for driving a word line by using the driving power; and
a fuse array suitable for outputting information programmed in a fuse that is activated by the driven word line through a bit line.

2. The fuse array circuit of claim 1, wherein the read operation period includes first and second read periods, and the driving power has a first voltage level in the first read period and has a second voltage level in the second read period.

3. The fuse array circuit of claim 2, wherein the power generation block comprises:
a first supply section suitable for supplying a power having the first voltage level to the driving power; and
a second supply section suitable for supplying a power having the second voltage level to the driving power.

4. The fuse array circuit of claim 3, further comprising:
a selection transistor coupled between the fuse and the bit line.

5. The fuse array circuit of claim 4, wherein the word line comprises:
a program word line coupled to the fuse; and
a read word line coupled to the selection transistor.

6. The fuse array circuit of claim 5, wherein the driving power is applied to the read word line.

7. The fuse array circuit of claim 2, wherein the first voltage level is higher than the second voltage level.

8. A fuse array circuit comprising:
a power generation block suitable for generating a driving power that is level-shifted at least once in a read operation period;
a level control block suitable for controlling a voltage level of the driving power based on state information of each of a plurality of fuses;
a word line driving block suitable for driving a word line corresponding to each of the fuses by using the driving power; and
a fuse array suitable for outputting information programmed in a fuse that is activated by the corresponding word line of the fuses through a bit line.

9. The fuse array circuit of claim 8, wherein the state information of each of the fuses corresponds to a resistance value of each of the fuses after a programming operation.

10. The fuse array circuit of claim 8, wherein the voltage levels of the driving power are different from one another according to resistance values of the fuses.

11. The fuse array circuit of claim 8, wherein a slope of a voltage level of the bit line is proportional to a voltage level of the driving power.

12. A semiconductor system comprising:
a semiconductor device with a fuse array circuit suitable for controlling a read operation period of the fuse array circuit based on initialization time information; and
a controller suitable for providing the initialization time information and controlling the semiconductor device after the read operation period.

13. The semiconductor system of claim 12, wherein the fuse array circuit comprises:
a power generation block suitable for generating a driving power to be level-shifted at least once in the read operation period;
a level control block suitable for controlling a voltage level of the driving power based on the initialization time information;
a word line driving block suitable for driving a word line by using the driving power; and
a fuse array suitable for outputting information programmed in a fuse that is activated by the driven word line through a bit line.

14. The semiconductor system of claim 12, wherein a plurality of fuses included in the fuse array have sensing operation time points corresponding to the initialization time information.

15. The semiconductor system of claim 12, wherein the level control block fixes a level shifting point in time of the driving power to a predetermined point in time, and controls the voltage level of the driving power based on the initialization time information.

16. The semiconductor system of claim 12, wherein the level control block fixes the voltage level of the driving power to a predetermined level, and controls a level shifting in time point in time of the driving power based on the initialization time information.
